(19) United States
(12) Patent Application Publication
(10) Pub. No.: US 2024/0258280 A1
(43) Pub. Date: Aug. 1, 2024

(54) IMAGE COMPENSATION DEVICE

(71) Applicant: Industrial Technology Research Institute, Hsinchu (TW)

(72) Inventors: Ren-Lu Chen, Hsinchu County (TW); Chy-Lin Wang, Hsinchu County (TW); Li-Chun Huang, Hsinchu City (TW); Chia-Hsin Chao, Hsinchu County (TW); Ming-Hsien Wu, Hsinchu County (TW)

(73) Assignee: Industrial Technology Research Institute, Hsinchu (TW)

(21) Appl. No.: 18/396,725

(22) Filed: Dec. 27, 2023

Related U.S. Application Data
(60) Provisional application No. 63/482,302, filed on Jan. 31, 2023.

(51) Int. Cl. H01L 25/075; H01L 33/58

(52) U.S. Cl. CPC H01L 25/0753; H01L 33/58

(57) ABSTRACT

An image compensation device including a substrate and island display units is provided. The substrate includes a central area and configuration rings surrounding the central area and spaced apart from the central area at different intervals. The island display units are disposed on the substrate. One of the island display units is disposed at the central area, and the other island display units are respectively disposed at the configuration rings. Each island display unit includes a real display area and a dummy display area located around the real display area, and includes real pixels and dummy pixels. The real pixels are disposed in the real display area. The dummy pixels are disposed in the dummy display area, and a number of the dummy pixels is greater than a number of the real pixels to compensate for a display image spliced by discrete images.

### CROSS-REFERENCE TO RELATED APPLICATION

This application claims the priority benefit of U.S. provisional application Ser. No. 63/482,302, filed on Jan. 31, 2023. The entirety of the above-mentioned patent application is hereby incorporated by reference herein and made a part of this specification.

### TECHNICAL FIELD

The disclosure relates to a display device, and in particular to an image compensation device.

### BACKGROUND

With the development of light-emitting diode display techniques, the size of the light-emitting diode die is gradually reduced to several micrometers (μm). A micro light-emitting diode (micro LED) has advantages such as long life, small size, high shock resistance, low heat generation, and low power consumption and has also been used in flat panel and small-sized displays. In recent years, the micro LED has developed towards multi-color and high brightness. Therefore, in future technological applications, there will be more application fields and levels, thereby replacing the general LED.

In the current display field, the micro LED may be used in an island panel having light-transmitting properties. In current techniques, the existing island arrangement of pixels and lens arrays may improve the transparency and transmittance of the panel. However, since the display beam passes through the lens array, there may be forward/off-axis aberration due to the optical conditions of the lens, such that the display screen is deformed, and therefore the user's observation screen display is deformed or spliced out of position. In addition, if there is an error in the position of each of the island display pixels, an error in the arrangement position of the lens array, parallax of users, or an error in element assembly alignment, it may also cause distortion of the display screen. Therefore, how to maintain the integrity of a splicedimage is one of the important issues in the art.

### SUMMARY

The disclosure provides an image compensation device including a substrate and a plurality of island display units. The substrate includes a central area and a plurality of configuration rings surrounding the central area and spaced apart from the central area at different intervals. The plurality of island display units are disposed on the substrate. One of the plurality of island display units is disposed at the central area, and the other island display units are respectively disposed at the plurality of configuration rings. Each of the plurality of island display units includes a real display area and a dummy display area located around the real display area, and includes a plurality of real pixels and a plurality of dummy pixels. The plurality of real pixels are disposed in the real display area. The plurality of dummy pixels are disposed in the dummy display area, and a number of the plurality of dummy pixels is greater than a number of the plurality of real pixels to compensate for a display image spliced by a plurality of discrete images.

Several exemplary embodiments accompanied with figures are described in detail below to further describe the disclosure in details.

### BRIEF DESCRIPTION OF THE DRAWINGS

FIG. 1A and FIG. 1B are respectively a schematic front view of an image compensation device and a schematic side view of projecting a display screen of an embodiment of the disclosure.

FIG. 2A and FIG. 2B are respectively a schematic front view of an image compensation device and a schematic side view of projecting a display screen of another embodiment of the disclosure.

FIG. 3 is a schematic diagram of a plurality of island display units of an embodiment of the disclosure.

FIG. 4 is a schematic diagram of a plurality of island display units of another embodiment of the disclosure.

FIG. 5A and FIG. 5B are respectively schematic diagrams of one of a plurality of island display units of different embodiments of the disclosure.

FIG. 6A to FIG. 6C are respectively schematic diagrams of a plurality of island display units of different embodiments.

FIG. 7 is a schematic side view of an image compensation device of another embodiment of the disclosure.

FIG. 8 is a schematic side view of an image compensation device projecting a display screen of another embodiment of the disclosure.

FIG. 9 is a schematic diagram of a display screen projected by the image compensation device of FIG. 8.

FIG. 10 is a schematic front view of the island display unit of FIG. 8.

FIG. 11 is a schematic side view of an image compensation device projecting a display screen of another embodiment of the disclosure.

FIG. 12 is a schematic front view of the image compensation device of FIG. 11.

### DETAILED DESCRIPTION OF DISCLOSURED EMBODIMENTS

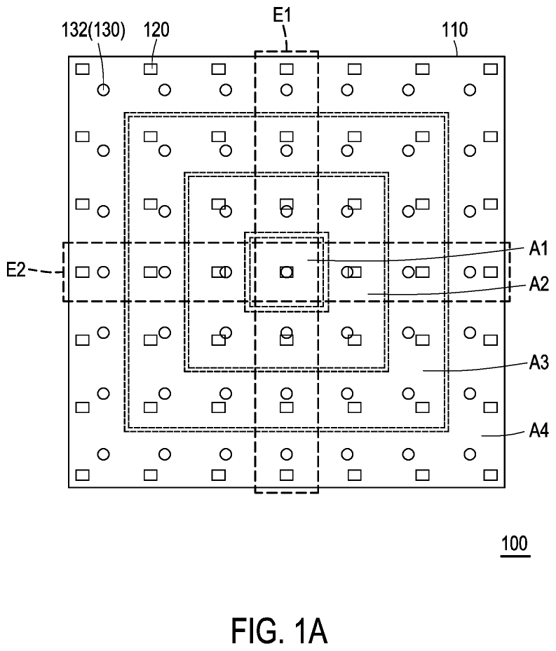

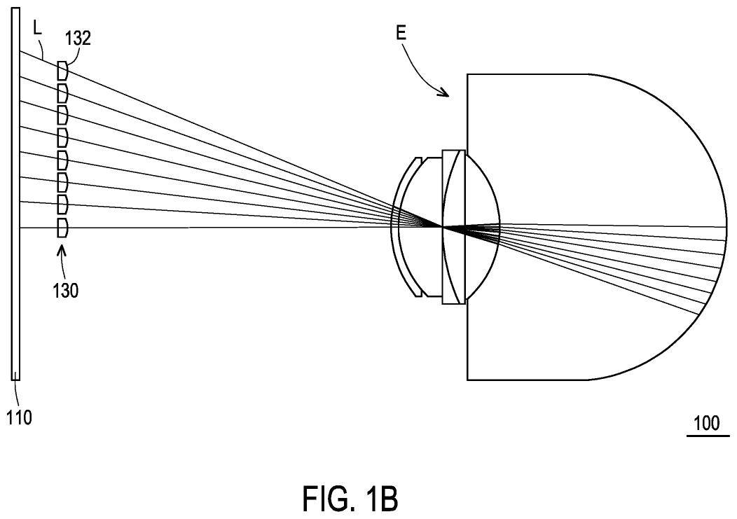

FIG. 1A and FIG. 1B are respectively a schematic front view of an image compensation device and a schematic side view of projecting a display screen of an embodiment of the disclosure. Please refer to FIG. 1A and FIG. 1B. A human eye E shown in FIG. 1B is a human eye optical system simulated by optical software using a similar optical component, and is therefore represented by an optical component. The present embodiment provides an image compensation device 100 including a substrate 110 and a plurality of island display units 120. For example, the substrate 110 may be a substrate having light-transmitting properties, and may be, for example, glass, resin, or plastic. In the present embodiment, the image compensation device 100 is a micro light-emitting diode (micro LED) island light-transmitting panel. The area and the arrangement shape of the island display units 120 may be freely adjusted to optimize the spliced display screen in which the image beam reaches the human eye E (or pupil) to correct and optimize the image of the main display area, thereby alleviating optical quality issues such as optical aberration of the display screen, uneven brightness at the seams in the display screen, and/or discontinuous screens, thereby further improving the optical quality of the display screen.

The plurality of island display units 120 are disposed on the substrate 110. Each of the island display units 120 includes a plurality of pixels for providing a light beam L having image frame information. Each of the pixels includes, for example, at least one micro LED. The plurality of island display units 120 may be disposed on a single substrate 110, or the plurality of island display units 120 may be disposed on a plurality of substrates, and then the plurality of substrates are spliced into a single substrate 110 (not shown). An optical component 130 is disposed on the transmission path of the light beam L to guide the light beam to the human eye E. Specifically, the substrate 110 includes a central area A1 and a plurality of configuration rings A2, A3, and A4 surrounding the central area A1 and spaced apart from the central area A1 at different intervals, and one of the plurality of island display units 120 is disposed at the central area A1 (that is, the central area A1 has a single island display unit 120), and the other of the plurality of island display units 120 are respectively disposed at the plurality of configuration rings A2, A3, and A4. In particular, the central area A1 and the plurality of configuration rings A2, A3, and A4 are continuous in substantial structure. In other words, the central area A1 and the plurality of configuration rings A2, A3, and A4 may be defined as different areas on the substrate 110, and these areas are not overlapped with each other. For example, in the present embodiment, the minimum spacings between adjacent configuration rings A2, A3, and A4 are the same as each other, and the numbers of the island display units 120 in different configuration rings A2, A3, and A4 are different from each other.

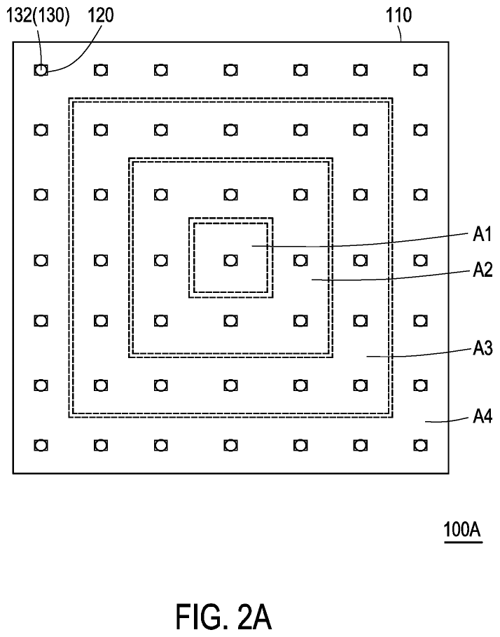

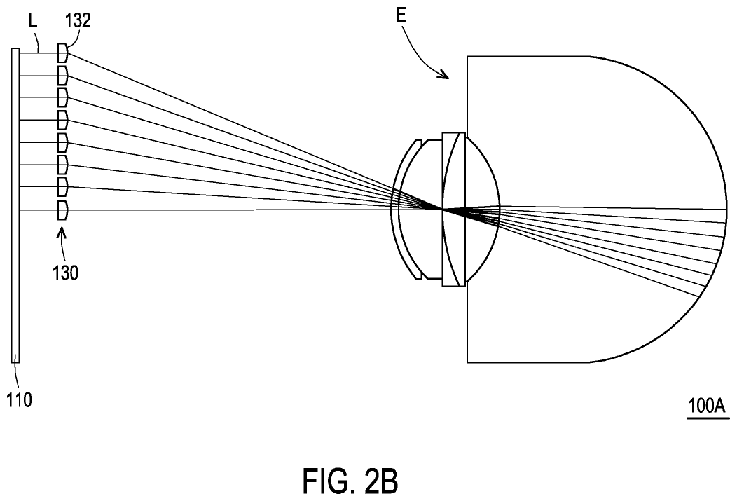

In the present embodiment, the image compensation device 100 further includes the optical component 130 disposed at a relative position of the plurality of island display units 120 for displaying a spliced image having missing seams, overlaps, or other types of distortion. The optical component 130 includes a plurality of refractive elements 132. The refractive elements 132 may be microlenses, metalenses, Fresnel lenses, diffractive element lenses, or any number of combinations thereof. The plurality of refractive elements 132 are respectively disposed corresponding to the plurality of island display units 120. The distance of the plurality of refractive elements 132 and the plurality of island display units 120 is greater as the distance of the plurality of island display units 120 and the central area A1 is increased. That is, at a position farther from the central area A1, the distance between each corresponding refractive element 132 and the island display unit 120 is greater, or it may be said that the refractive elements 132 and the plurality of island display units 120 are disposed in a misaligned manner. In other words, the number of the plurality of island display units 120 is increased as the spacing of the plurality of disposed configuration rings A2, A3, and A4 and the central area A1 is greater. The island display unit 120 in the central area A1 is overlapped with the refractive element 132. In the present embodiment, the plurality of island display units 120 are arranged in an array on the substrate 110, and if the plurality of island display units 120 are arranged in M×M, and M is greater than or equal to 3, as shown in FIG. 1A. For example, in the present embodiment, the plurality of island display units 120 are arranged in a 7×7 arrangement and are respectively disposed in the central area A1 and three configuration rings A2, A3, and A4, and the interval range thereof is 1 mm to 2 mm, but the disclosure is not limited thereto. In a different embodiment, the plurality of island display units 120 are arranged in an array on the substrate 110, and the plurality of island display units 120 are arranged in M1×M2, wherein M1 and M2 are both positive integers, and M1 and M2 are different. In a different embodiment, each of the island display units 120 of an image compensation device 100A is overlapped with the corresponding refractive element 132, that is, the spacing of each of the island display units 120 is equal to the spacing of each of the refractive elements, as shown in FIG. 2A and FIG. 2B.

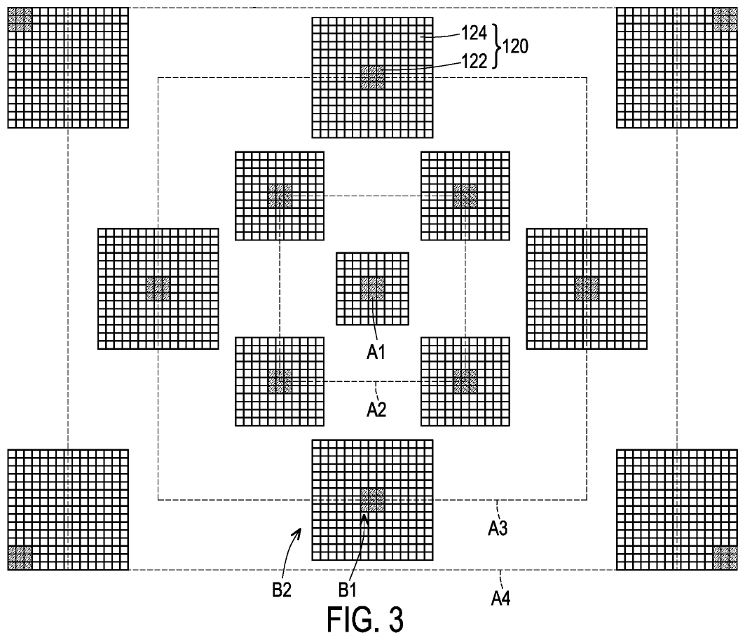

FIG. 3 is a schematic diagram of a plurality of island display units of an embodiment of the disclosure. For convenience of explanation, the central area A1 and the three configuration rings A2, A3, and A4 in FIG. 3 are represented by line segments, and a portion of the island display units 120 is shown. In addition, the plurality of island display units 120 shown in FIG. 3 may be applied to at least the image compensation device 100 of FIG. 1A, so the following description is exemplified as such. Please refer to FIG. 1A and FIG. 3. Specifically, each of the island display units 120 includes a real display area B1 and a dummy display area B2 located around the real display area B1, and each of the island display units 120 includes a plurality of real pixels 122 and a plurality of dummy pixels 124. In particular, the plurality of real pixels 122 are disposed in the real display area B1, and the plurality of dummy pixels 124 are disposed in the dummy display area B2. The present embodiment does not limit the range of the spacing of adjacent pixels thereof, and may be designed to be from 0.1 microns to several centimeters according to different requirements, such as 0.1 microns to 100 microns, 100 microns to 1 centimeter, or 1 centimeter to 10 centimeters. In addition, the number of the plurality of dummy pixels 124 is greater than the number of the plurality of real pixels 122. Therefore, when the display screen needs to be compensated, via the optical effects of the plurality of dummy pixels 124 disposed around the plurality of real pixels 122, a display image spliced by a plurality of discrete images (i.e., image screens generated by the plurality of real pixels 122 not compensated by the plurality of dummy pixels 124) is compensated to achieve the effect of correcting and optimizing the image of the main display area. For example: when the display screen is compensated, one or a plurality of dummy pixels in the dummy display area B2 are lit irregularly; and when the display screen is not compensated, the dummy pixels are not lit up in the dummy display area B2. In this way, optical quality issues such as optical aberration of the island display screen, uneven brightness at seams in the display screen, and/or discontinuous screens may be alleviated, thereby improving the optical quality of the display screen.

More specifically, the number ratio and the arrangement method of the plurality of real pixels 122 and the plurality of dummy pixels 124 in different island display units 120 are associated with different positions of the island display units 120 on the substrate 110. In a single island display unit 120, the numbers of the plurality of real pixels 122 are the same as each other, and the number of the plurality of dummy pixels 124 is increased as the spacing of the plurality of disposed configuration rings A2, A3, A4 and the central area A1 is greater. That is, in a single island display unit 120, the sum of the numbers of the plurality of real pixels 122 and the plurality of dummy pixels 124 is increased as the spacing of the plurality of disposed configuration rings A2, A3, A4 and the central area A1 is greater.

For example, in the present embodiment, the plurality of island display units 120 are arranged in a 7×7 matrix, and therefore the central area A1 has a single island display unit 120, the configuration ring A2 closest to the central area A1 has 8 island display units 120, and the configuration ring A3 second closest to the central area A1 has 16 island display units 120, and the configuration ring A3 farthest from the central area A1 has 24 island display units 120, as shown in FIG. 1A. Moreover, in the configuration of the dummy pixels 124, the number of rows of outwardly extending dummy pixels 124 may be designed in a manner of N/(K×n), wherein N is the resolution/number of islands in the x direction or the y direction; when N is an even number, n is greater than zero and is an even number, and N may be divided by n; when N is an odd number, n is greater than zero and is an odd number, and N may be evenly divided by n; and K is the number of turns from the outermost arrangement. For example, in the present embodiment, the resolution is 360×360, the number of islands is 15×15, so N is 24; since N is an even number and n is 2, in the island display unit 120 located at the central area A1, N/(K×n) is 24/(4×2)=3, and three additional rows of the dummy pixels 124 are disposed toward each of the four outer sides of the real pixels 122 to form an island display unit 120 of 9×9 pixels having 9 real pixels 122 and 72 dummy pixels 124. In each of the island display units 120 located in the configuration ring A2 closest to the central area A1, N/(K×n) is 24/(3×2)=4, and four additional rows of the dummy pixels 124 are disposed toward each of the four outer sides of the real pixels 122 to form an island display unit 120 of 11×11 pixels having 9 real pixels 122 and 112 dummy pixels 124. In each of the island display units 120 located in the configuration ring A3 second closest to the central area A1, N/(K×n) is 24/(2×2)=6, and six additional rows of the dummy pixels 124 are disposed toward each of the four outer sides of the real pixels 122 to form an island display unit 120 of 15×15 pixels having 9 real pixels 122 and 216 dummy pixels 124. In the configuration ring A4 located farthest from the central area A1, N/(K×n) is 24/(1×2)=12, the real pixels 122 of each of the island display units 120 are disposed at a side away from the central area A1, and an additional 12 rows of the dummy pixels 124 are disposed at two or three sides of the central area A1 of the real pixels 122 to form an island display unit 120 of 15×15 pixels having 9 real pixels 122 and 216 dummy pixels 124, as shown in FIG. 3. In a different embodiment, the real pixels 122 of each of the island display units 120 located in the configuration ring A4 farthest from the central area A1 may also be designed to be disposed in the central area of each of the island display units 120, and the disclosure is not limited thereto. Therefore, the image of the main display area may be corrected and optimized via the optical effects of the plurality of dummy pixels 124 disposed around the plurality of real pixels 122 to further improve the optical quality of the display screen. What is more worth mentioning is that in the present embodiment, when the dummy pixels 124 are not disposed, the transparency of the image compensation device 100 is, for example, 70%. After the dummy pixels 124 are disposed in each of the island display units 120, the transparency of the image compensation device 100 may still be maintained at 50% to 60%, and therefore the overall transmission effect is not affected. In different embodiments, the plurality of island display units 120 are arranged in a matrix of M×M, wherein M is an even number greater than or equal to 2. For example, the plurality of island display units 120 are arranged in a 6×6 matrix. The difference from the 7×7 configuration is that areas E1 and E2 are not included (see FIG. 1A), and the rest of the configuration is the same. When the image screen is displayed to the human eye E, the compensated displayed image is spliced by the optical effect of the optical component 130 to form a spliced image with no visible seams.

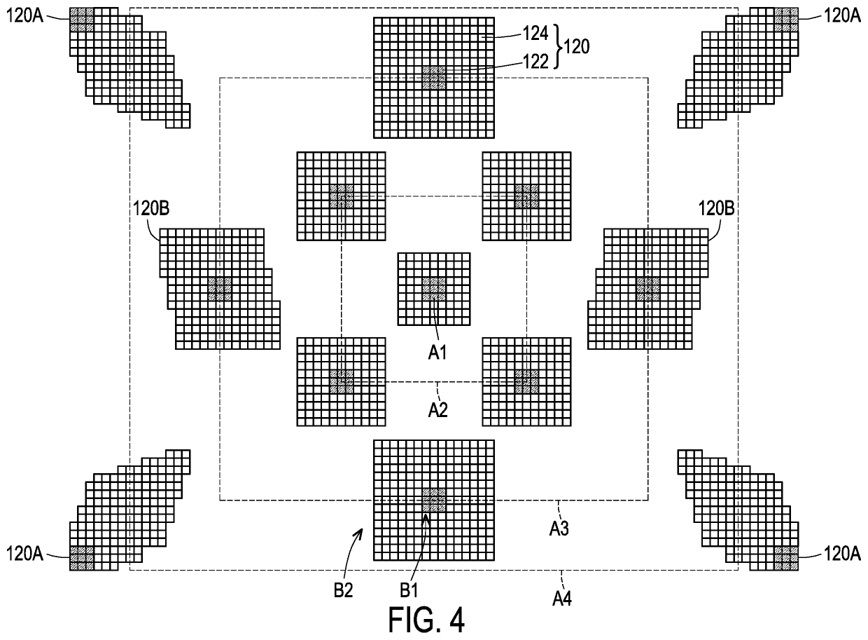

FIG. 4 is a schematic diagram of a plurality of island display units of another embodiment of the disclosure. For convenience of explanation, the central area A1 and the three configuration rings A2, A3, and A4 in FIG. 4 are represented by line segments, and a portion of island display units 120, 120A, and 120B is shown. In addition, the plurality of island display units 120, 120A, and 120B shown in FIG. 4 may be applied to at least the image compensation device 100 of FIG. 1A, so the following description is exemplified as such. Please refer to FIG. 1A and FIG. 4. The plurality of island display units 120, 120A, and 120B shown in FIG. 4 are similar to the plurality of island display units 120 shown in FIG. 3. The difference between the two is that in the present embodiment, in the configuration ring A4 farthest from the central area A1, the appearance of the coverage range of the plurality of island display units 120A is a rhombus. Specifically, in the configuration ring A4, the appearance of the coverage range of the plurality of island display units 120A located at the four corners is a rhombus, thereby reducing the number of the dummy pixels 124 not commonly used so that the dummy pixels 124 may be concentrated in a more commonly used area, thereby improving the overall light transmittance. The appearance of the coverage range of the other of the plurality of island display units 120 not located at the four corners is still a rectangle. In addition, in the configuration ring A3 second farthest from the central area A1, the appearance of the coverage range of the plurality of island display units 120B is a parallelogram. Specifically, in the configuration ring A3, the appearance of the coverage range of the island display unit 120B located at two sides of the horizontal line passing through the central area A1 is a parallelogram, same as the configuration ring A4, thereby reducing the number of the dummy pixels 124 not commonly used, so that the dummy pixels 124 may be concentrated in a more commonly used area. The appearance of the coverage range of the other of the plurality of island display units 120 at two sides of the horizontal line that do not pass through the central area A1 is still a rectangle, but the disclosure is not limited thereto. In this way, the effect of correcting and optimizing the image of the main display area may be improved, thereby improving the optical quality of the display screen.

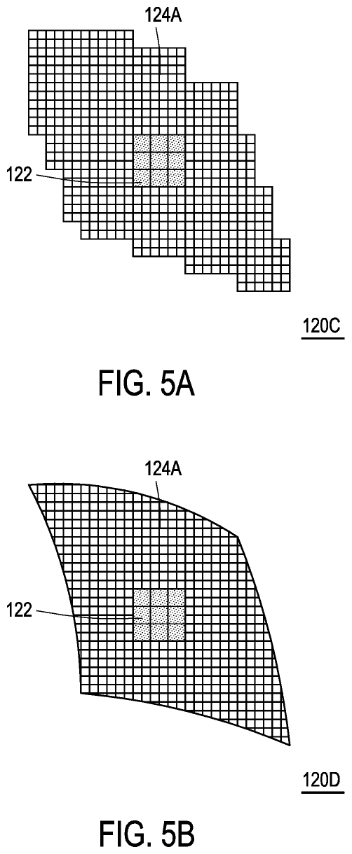

FIG. 5A and FIG. 5B are respectively schematic diagrams of one of a plurality of island display units of different embodiments of the disclosure. Please first refer to FIG. 5A. An island display unit 120C shown in FIG. 5A is similar to the island display unit 120A shown in FIG. 4 located in the configuration ring A4 and for which the appearance of the coverage range is a rhombus. The difference between the two is that in the present embodiment, the interval period of a dummy pixel 124A may be designed to be reduced to the interval period of the real pixels 122 divided by a positive integer multiple. For example, in the present embodiment, the size of the dummy pixel 124A is the interval period of the real pixels 122 divided by 2. Therefore, the peripheral compensated image in the display screen may be made more detailed, thereby improving the optical quality of the display screen. Please refer to FIG. 5B. An island display unit 120D shown in FIG. 5B is similar to the island display unit 120C shown in FIG. 5A. The difference between the two is that in the present embodiment, the dummy pixel 124A located at the edge may be designed in an irregular shape. Therefore, the edge-compensated image in the display screen may also be made more detailed, thereby improving the optical quality of the display screen.

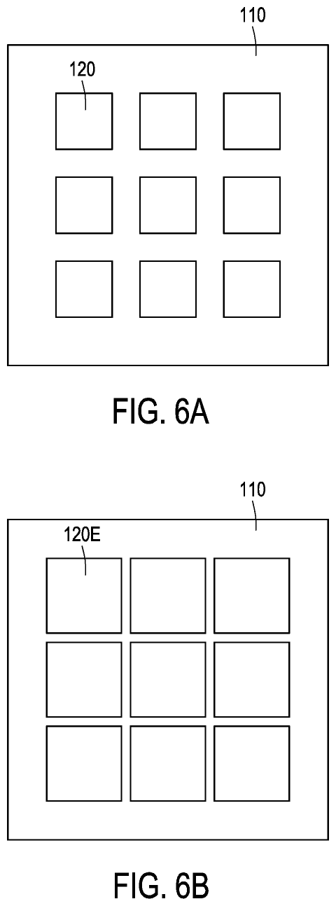

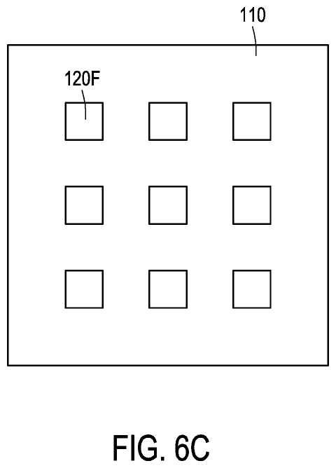

FIG. 6A to FIG. 6C are respectively schematic diagrams of a plurality of island display units of different embodiments. Please refer to FIG. 6A to FIG. 6C. In a different embodiment, the range size of the island display units 120 may be designed differently according to different vision levels of users. For example, the island display units 120 shown in FIG. 6A have a moderate size. Each of the island display units is composed of, for example, 10×10 pixels on average, and may be used by users with normal vision. Moreover, compared with the island display units 120 shown in FIG. 6A, island display units 120E shown in FIG. 6B have a greater size. On average, each of the island display units is composed of, for example, 12×12 pixels. Therefore, the area of the island display units 120E may be increased to compensate for the separation of the image seen by users with myopia when observing the image. Moreover, compared with the island display units 120 shown in FIG. 6A, island display units 120F shown in FIG. 6C have a smaller size. On average, each of the island display units is composed of, for example, 9×9 pixels. Therefore, the area of the island display units 120E may be reduced to compensate for the overlapping of the image seen by users with hyperopia when observing the image. In an embodiment, as shown in FIG. 6C, based on the size of the island display units 120F, each of the island display units is composed of, for example, 9×9 pixels on average, and dummy pixels of, for example, 12×12 are added around each of the island display units 120F. Therefore, when users with myopia view an image, each of the island display units 120F is activated; when used by users with normal vision, each of the island display units 120F is activated with dummy pixels to achieve that each of the island display areas presents a pixel area of, for example, 10×10; and when users with hyperopia view an image, each of the island display units 120F is activated with dummy pixels to achieve that each of the island display areas presents a pixel area of, for example, 12×12.

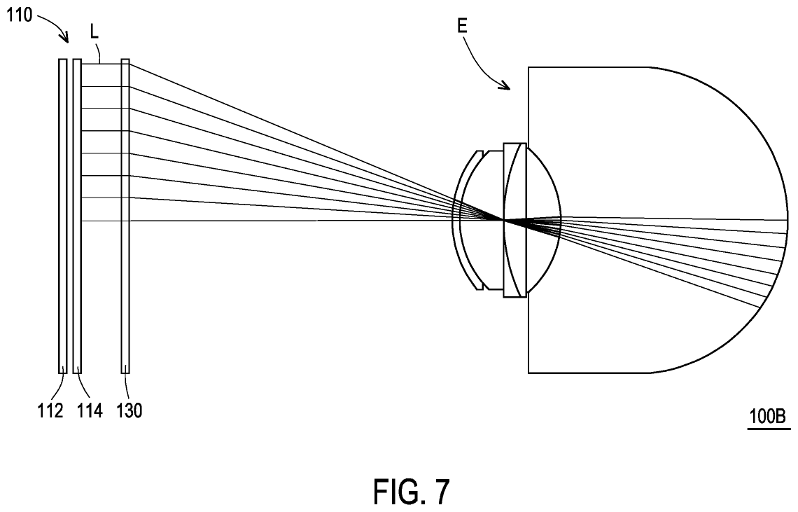

FIG. 7 is a schematic side view of an image compensation device of another embodiment of the disclosure. Please refer to FIG. 7. An image compensation device 100B shown in the present embodiment is similar to the image compensation device 100 shown in FIG. 1B. The difference between the two is that in the present embodiment, the substrate 110 includes a first portion 112 and a second portion 114 located on different planes. Therefore, a portion of the pixel structure may be selectively disposed at the first portion 112, and another portion of the pixel structure may be disposed at the second portion 114, so that different pixels are located on different focal planes to produce a soft focus effect. In other words, in each of the island display units, the focal planes of the plurality of real pixels are different from the focal planes of the plurality of dummy pixels. In other words, in each of the island display units, the plurality of real pixels and the plurality of dummy pixels are located on different planes. For example, in an embodiment, it may be designed to dispose the real pixels at the first portion 112 farther from the optical component 130, and to dispose the dummy pixels at the second portion 114 closer to the optical component 130. However, the disclosure is not limited thereto.

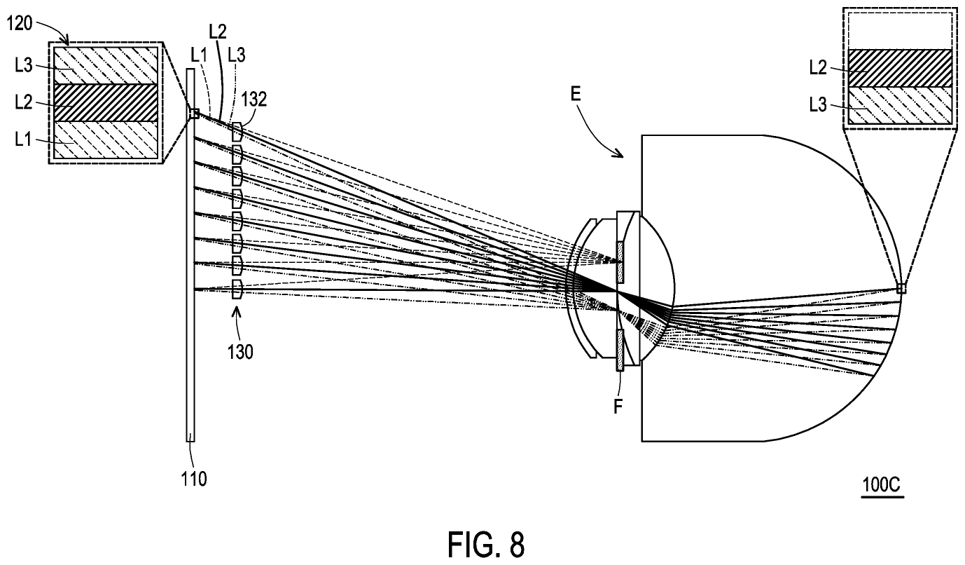

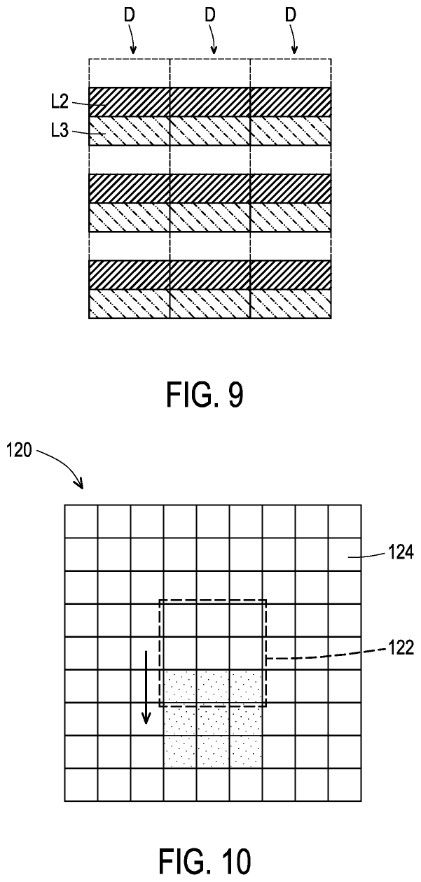

FIG. 8 is a schematic side view of an image compensation device projecting a display screen of another embodiment of the disclosure. FIG. 9 is a schematic diagram of a display screen projected by the image compensation device of FIG. 8. FIG. 10 is a schematic front view of the island display unit of FIG. 8. Please refer to FIG. 8 to FIG. 10. In particular, FIG. 8 shows the light paths of a green beam L1, a red beam L2, and a blue beam L3 respectively. The green, red, and blue light rays represent the bottom, middle, and top areas of the island respectively. In another embodiment, if a pupil F of the human eye E is not aligned with the simulated eye box, for example, the lower area of the island display unit 120 (marked by the green light beam L1) is blocked by the pupil F, as shown in FIG. 8, and compensation may be performed by adjusting an image compensation device 100C. Specifically, in the present embodiment, the image screen displayed after the lower area of the island (marked by the green light beam L1) is blocked by the pupil F is a plurality of discontinuous sub-display screens D, as shown in FIG. 9. Therefore, the dummy pixels 124 disposed in each of the island display units 120 may be further utilized to light up a portion of the dummy pixels 124 and turn off a portion of the real pixels 122, as shown in FIG. 10, to achieve the effect of panning the display area, so that the lower area of the compensated island display unit 120 (marked by the green light beam L1) is not blocked by the pupil F, thereby obtaining a complete display screen.

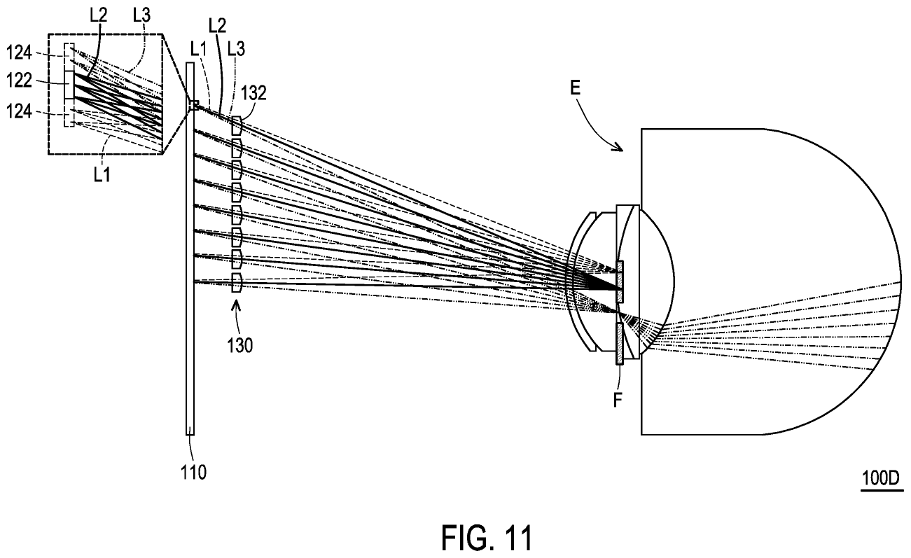

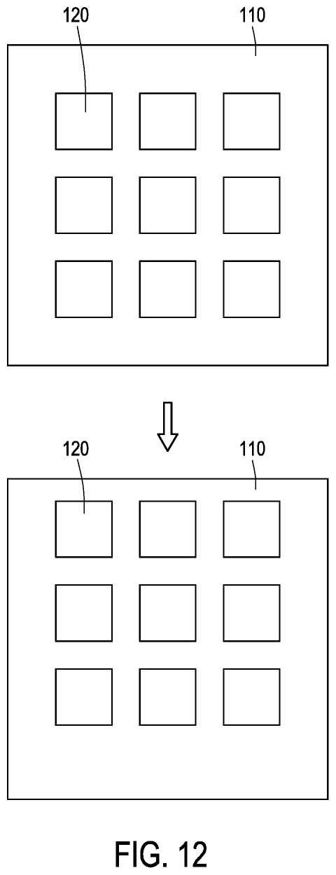

FIG. 11 is a schematic side view of an image compensation device projecting a display screen of another embodiment of the disclosure. FIG. 12 is a schematic front view of the image compensation device of FIG. 11. Please refer to FIG. 11 and FIG. 12. In particular, FIG. 11 shows that when the pupil offset position is greater and is not aligned with the eye box position, there is a situation where the image may not be seen at all. This is because the red light beam L2 is a design value so that the entire real display area of the island display units 120 may display an image at the retina via the pupil. The green light beam L1 represents a portion of the dummy display area in the island display units 120, which is located below the original designed real display area. The light path of the blue light beam L3 represents another portion of the dummy display area, which is located above the original designed real display area. In the present embodiment, if the pupil F of the human eye E is outside the eye box area, for example, the pupil F is below the eye box position, the real display area of the red light beam L2 is blocked by the pupil F, and the image is not visible at all, as shown in FIG. 11. In this case, compensation may be performed by adjusting an image compensation device 100D. The real pixels and the dummy pixels in each of the island display units 120 using the island display units 120 on the substrate 110 (for example, the display area of each of the island display units 120 is panned to the position of the dummy pixel island area of the blue light beam L3), so that the light beam of the dummy display area at the position of the original blue light beam L3 may enter the pupil F, thereby obtaining a perfect display screen.

It is worth mentioning that a dummy display area is added next to the real display area. The area of these dummy display areas may be designed to be about 0.5 times to 5 times the area of the real display area. Therefore, the pupil position may be captured using eye tracking, and then the position of the dummy display area needs to be adjusted (even if the light beam may pass through the offset pupil position). Compensation may be performed using the position compensation method of adjusting the dummy display area of FIG. 11 to generate dynamic movement to align the eye box position with the offset pupil, so that the pupil has a greater offset range to properly see the image, thereby achieving the effect of pupil dilation.

Based on the above, in the image compensation device of the disclosure, the image compensation device includes the substrate, the plurality of island display units, and the optical member. In particular, the substrate has the central area and the plurality of configuration rings surrounding the central area and spaced apart from the central area at different intervals. The plurality of island display units are disposed on the substrate to provide light beams for displaying the image, and one of the plurality of island display units is disposed at the central area, and the other of the plurality of island display units are respectively disposed at the plurality of configuration rings. In particular, each of the island display units includes the plurality of real pixels disposed in the real display area and the plurality of dummy pixels disposed in the dummy display area, and the number of the dummy pixels is greater than the number of the real pixels. Therefore, the image of the main display area may be corrected and optimized via the optical effects of the plurality of dummy pixels disposed around the plurality of real pixels. In this way, optical quality issues such as optical aberration of the island display screen, uneven brightness at seams in the display screen, and/or discontinuous screens may be alleviated, thereby improving the optical quality of the display screen.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An image compensation device, comprising:
a substrate comprising a central area and a plurality of configuration rings surrounding the central area and spaced apart from the central area at different intervals; and
a plurality of island display units disposed on the substrate, one of the plurality of island display units is disposed in the central area, the other of the plurality of island display units are respectively disposed in the plurality of configuration rings, and each of the plurality of island display units comprises a real display area and a dummy display area located around the real display area, and comprises:
a plurality of real pixels disposed in the real display area; and
a plurality of dummy pixels disposed in the dummy display area, and a number of the plurality of dummy pixels is greater than a number of the plurality of real pixels to compensate for a display image spliced by a plurality of discrete images.

2. The image compensation device of claim 1, wherein minimum spacings of adjacent configuration rings are the same as each other.

3. The image compensation device of claim 1, wherein numbers of the plurality of island display units in different configuration rings are different from each other.

4. The image compensation device of claim 1, wherein the plurality of island display units are arranged in an array on the substrate.

5. The image compensation device of claim 4, wherein the plurality of island display units are arranged in M×M, and M is greater than or equal to 3.

6. The image compensation device of claim 1, further comprising an optical member disposed at a relative position of the plurality of island display units.

7. The image compensation device of claim 1, wherein a number of the plurality of island display units is increased as a spacing of the plurality of disposed configuration rings and the central area is greater.

8. The image compensation device of claim 1, wherein in a single island display unit, numbers of the plurality of real pixels are the same as each other.

9. The image compensation device of claim 1, wherein in a single island display unit, the number of the plurality of dummy pixels is increased as a spacing of the plurality of disposed configuration rings and the central area is greater.

10. The image compensation device of claim 1, wherein in a single island display unit, a sum of the numbers of the plurality of real pixels and the plurality of dummy pixels is increased as a spacing of the plurality of disposed configuration rings and the central area is greater.

11. The image compensation device of claim 1, wherein in the plurality of configuration rings farthest from the central area, the real display area in each of the plurality of island display units is located at a side away from the central area.

12. The image compensation device of claim 1, wherein in the plurality of configuration rings farthest from the central area, an appearance of a coverage range of the plurality of island display units is a rhombus.

13. The image compensation device of claim 1, wherein in the plurality of configuration circles second farthest from the central area, an appearance of a coverage range of the plurality of island display units is a parallelogram.

14. The image compensation device of claim 1, wherein in each of the plurality of island display units, focal planes of the plurality of real pixels are different from focal planes of the plurality of dummy pixels.

15. The image compensation device of claim 1, wherein in each of the plurality of island display units, the plurality of real pixels and the plurality of dummy pixels are located on different planes.

16. The image compensation device of claim 1, wherein the optical component comprises a plurality of refractive elements respectively disposed corresponding to the plurality of island display units, and a distance of the plurality of refractive elements and the plurality of island display units is greater as a distance of the plurality of island display units and the central area is increased.
